(19) United States
(12) Patent Application Publication
(10) Pub. No.: US 2013/0175411 A1
(43) Pub. Date: Jul. 11, 2013

(54) STAND ADAPTER FOR PROJECTOR OR RECORDING DEVICE

(71) Applicants: Youngil Kim, Seongnam City (KR); Matthew J. Esserman, Philadelphia, PA (US)

(72) Inventors: Youngil Kim, Seongnam City (KR); Matthew J. Esserman, Philadelphia, PA (US)

(21) Appl. No.: 13/346,696

(22) Filed: Jan. 9, 2012

(51) Int. Cl. H05K 7/00

(52) U.S. Cl. 248/121

(57) ABSTRACT

An imaging system is provided. The imaging system comprises a stand, adapter, and imaging device that allows for a imaging device's housing bottom to be free of female threaded holes for attaching to the stand, by positioning the female threaded hole within an adapter which is exterior of the imaging device's housing. The adapter does not occupy precious imaging device housing interior real estate thereby allowing the housing to be extremely compact. The imaging device comprises a mating system that removably secures the adapter. The imaging device is therefore removably secured to the stand via the adapter.

### FIELD OF THE INVENTION

The present invention relates generally to the field of imaging devices and stands therefor, and, more specifically, to adapters for supporting projectors or recording devices on stands.

### BACKGROUND OF THE INVENTION

Imaging devices such as projectors or recording devices (e.g. still cameras and video cameras/recorders) have typically been mounted on stands such as tripods utilizing a male threaded bolt-type fastener and corresponding female threaded hole arrangement. The bolt-type fastener is usually positioned at a platform of the stand while the female threaded hole is usually positioned at the bottom of the imaging device. However, the positioning of the female threaded hole takes up valuable real estate within the housing of the imaging device. As a result, the housing must be made larger to accommodate the female threaded hole and associated parts supporting the female threaded hole.

Thus, it is desirable to provide an system which is able to overcome the above disadvantages.

Therefore, a need exists to provide an imaging system that comprises a stand, adapter and imaging device that allows for a imaging device's housing bottom to be free of female threaded holes for attaching to the stand, by positioning the female threaded hole within an adapter which is exterior of the imaging device's housing. The adapter does not occupy precious imaging device housing interior real estate thereby allowing the housing to be extremely compact.

These and other advantages of the present invention will become more fully apparent from the detailed description of the invention hereinbelow.

### SUMMARY OF THE INVENTION

The present invention is directed to an imaging system. The imaging system comprises a stand including a platform and an upwardly extending threaded male fastener provided at the platform. The imaging system also comprises an adapter comprising a main body, wherein the main body comprises a main body bottom and a main body top, and wherein the main body bottom includes a threaded hole that threadably mates with the male fastener of the stand. The adapter also comprises a flange provided at the main body top. The imaging system further comprises an imaging device comprising a housing including a housing bottom and a mating system that removably secures the adapter. The imaging device is removably secured to the stand via the adapter. The housing bottom and mating system are free of female threaded holes that threadably mate with the male fastener of the stand. A removable platform battery having a battery mating system provided at the battery bottom is also contemplated.

### BRIEF DESCRIPTION OF THE DRAWINGS

For the present invention to be clearly understood and readily practiced, the present invention will be described in conjunction with the following figures, wherein:

FIG. 1 is an elevated perspective view of an imaging system that includes a projector, adapter, and stand, in accordance with a preferred embodiment of the present invention.

FIG. 2 is a perspective bottom view of the projector and the adapter shown in FIG. 1, wherein a mating system is provided at the bottom of the projector for removably securing the adapter, and wherein a process of inserting the adapter within the mating system is illustrated, in accordance with a preferred embodiment of the present invention.

FIG. 3 is a perspective bottom view of the projector, adapter, and mating system shown in FIG. 2, wherein completed insertion of the adapter within the mating system is illustrated, in accordance with a preferred embodiment of the present invention.

FIG. 4 is an enlarged, elevated and slightly different perspective view of the adapter and mating system shown in FIG. 3.

FIG. 5 is a side view of the projector, adapter, and mating system shown in FIG. 3.

FIG. 6 is an enlarged, elevated perspective bottom view of the adapter shown in FIGS. 1-5.

FIG. 7 is an enlarged, elevated perspective top view of the adapter shown in FIGS. 1-5.

FIG. 8 is a front view of a projector mounted on a platform battery, wherein the bottom of the platform battery includes thereat a battery mating system for removably securing an adapter, in accordance with a preferred embodiment of the present invention.

FIG. 9 is a perspective bottom view of the projector, platform battery, and battery mating system shown in FIG. 8, wherein completed insertion of the adapter within the battery mating system is illustrated, in accordance with a preferred embodiment of the present invention.

FIG. 10 is an elevated perspective top view of the platform battery shown in FIGS. 8 and 9.

FIG. 11 is an elevated perspective bottom view of the platform battery shown in FIGS. 8 and 9.

### DETAILED DESCRIPTION OF THE PREFERRED EMBODIMENTS

It is to be understood that the figures and descriptions of the present invention may have been simplified to illustrate elements that are relevant for a clear understanding of the present invention, while eliminating, for purposes of clarity, other elements found in a typical imaging device and stand therefor. Those of ordinary skill in the art will recognize that other elements may be desirable and/or required in order to implement the present invention. However, because such elements are well known in the art, and because they do not facilitate a better understanding of the present invention, a discussion of such elements is not provided herein. It is also to be understood that the drawings included herewith only provide diagrammatic representations of the presently preferred structures of the present invention and that structures falling within the scope of the present invention may include structures different than those shown in the drawings. Reference will now be made to the drawings wherein like structures are provided with like reference designations.

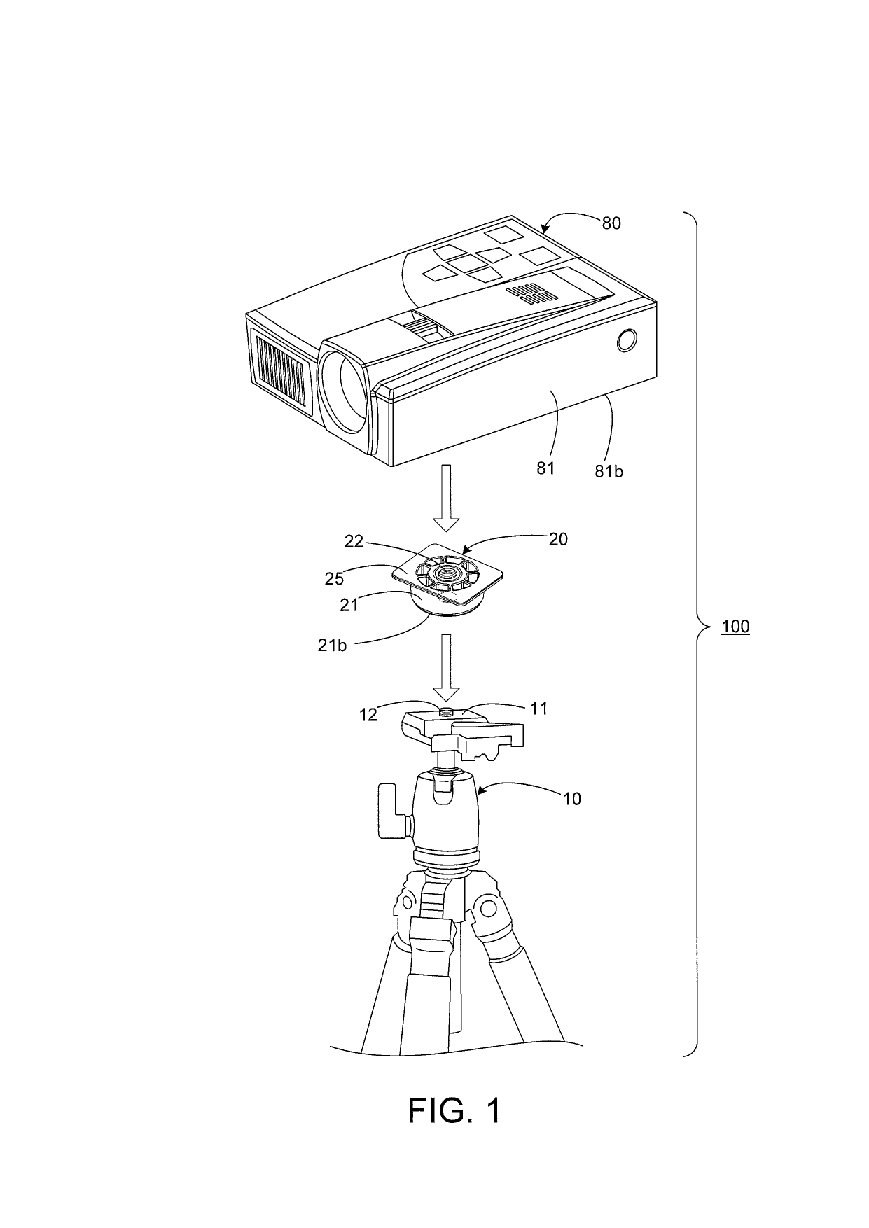

FIG. 1 is an elevated perspective view of an imaging system 100 that includes a projector 80, adapter 20, and stand 10, in accordance with a preferred embodiment of the present invention. The stand 10 may be a tripod (as depicted in FIG. 1) which is typically used in supporting imaging devices such as still cameras or video cameras/recorders. A stand having any number of legs may alternatively be employed. The stand could also be a mount with no legs.

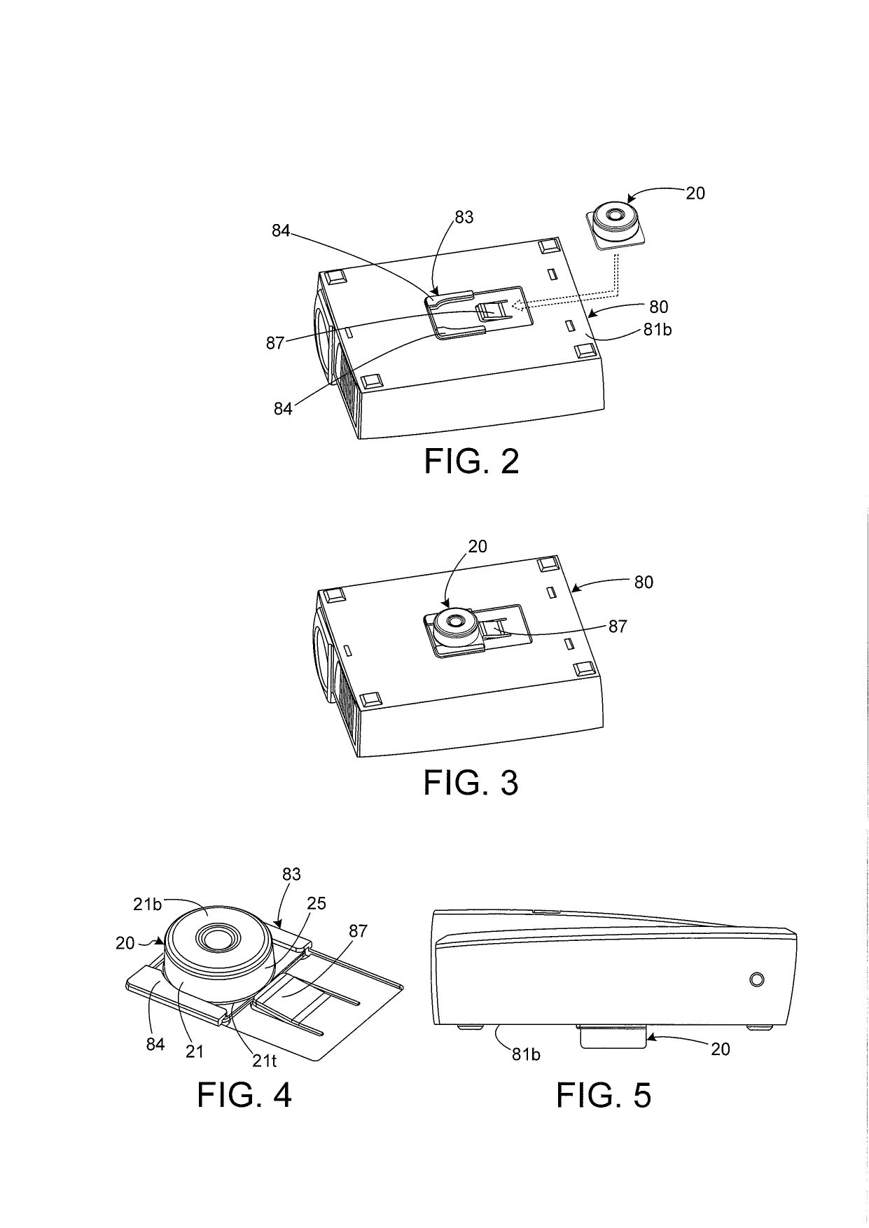

FIG. 2 is a perspective bottom view of the projector 80 and the adapter 20 shown in FIG. 1. A mating system 83 is provided at the bottom of the projector 80 for removably securing the adapter 20. A process of inserting the adapter 20 within the mating system 83 is illustrated, in accordance with a preferred embodiment of the present invention. The mating system is preferably made of plastic. Other materials such as metal can also be employed.

FIG. 3 is a perspective bottom view of the projector 80, adapter 20, and mating system 83 shown in FIG. 2, wherein completed insertion of the adapter 20 within the mating system 83 is illustrated, in accordance with a preferred embodiment of the present invention. A clip-on arrangement is thereby realized.

FIG. 4 is an enlarged, elevated and slightly different perspective view of the adapter 20 and mating system 83 shown in FIG. 3. An elastic tongue 87 is preferably provided to abut the main body 21 of the adapter 20 while the adapter 20 is inserted within the mating system 83. The mating system 83 also includes a slot system 84 that removably secures the flange 25 of the adapter 20 while the adapter 20 is inserted within the mating system 83. The slot system preferable removably secures opposite edges of the flange 25. However, any number of flange edges may alternatively be removably secured by the slot system 84.

FIG. 5 is a side view of the projector 80, adapter 20, and mating system 83 shown in FIG. 3.

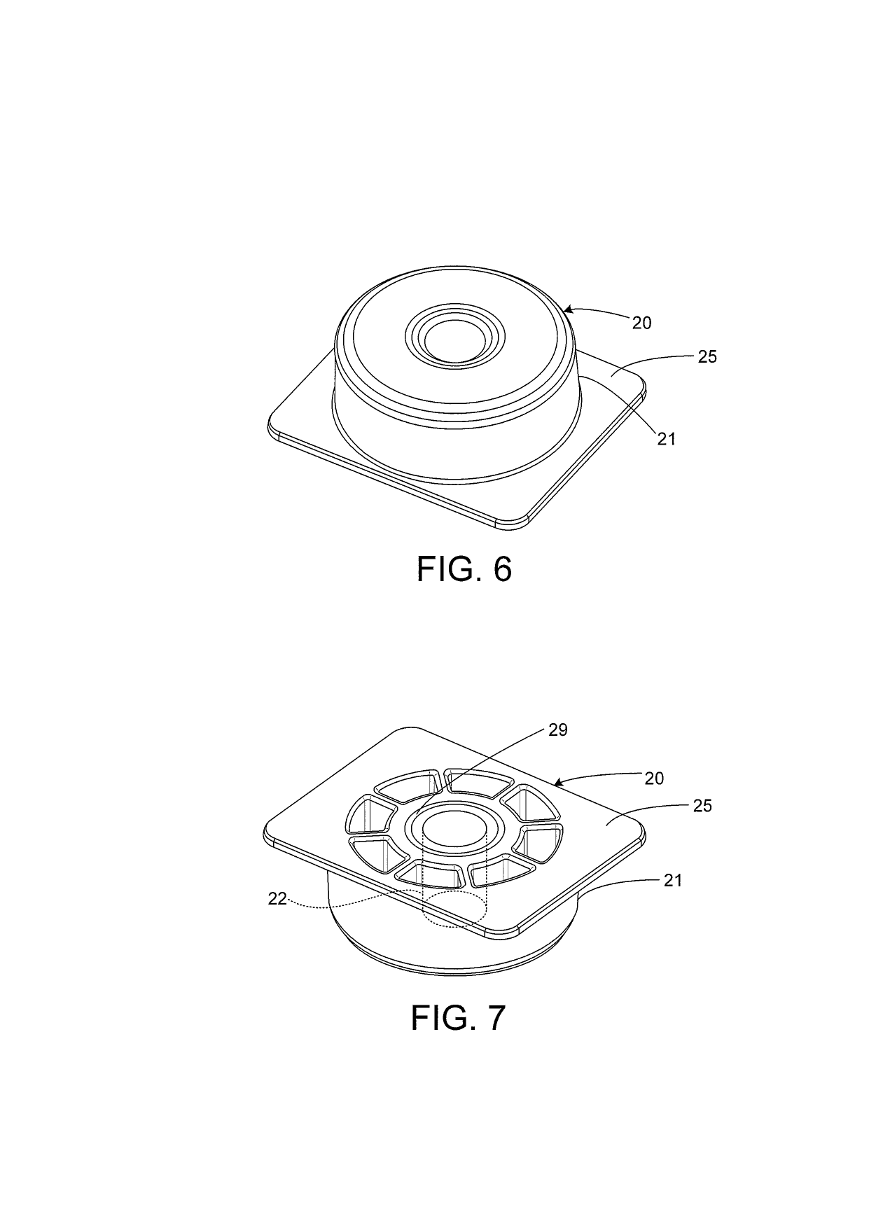

FIG. 6 is an enlarged, elevated perspective bottom view of the adapter 20 shown in FIGS. 1-5.

FIG. 7 is an enlarged, elevated perspective top view of the adapter 20 shown in FIGS. 1-5.

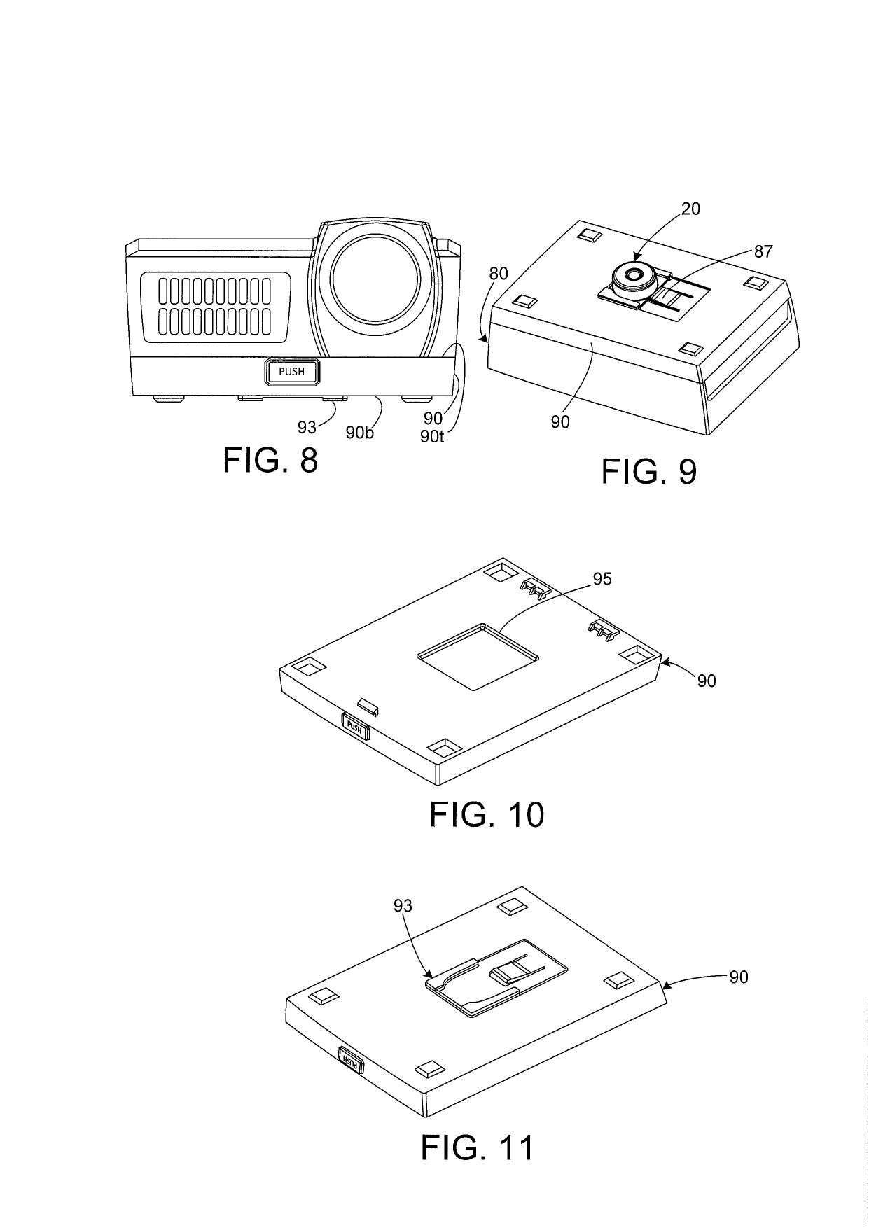

FIG. 8 is a front view of a projector 80 mounted on a platform battery 90, wherein the bottom 90b of the platform battery 90 includes thereat a battery mating system 93 for removably securing an adapter 20, in accordance with a preferred embodiment of the present invention.

FIG. 9 is a perspective bottom view of the projector 80, platform battery 90, and battery mating system 93 shown in FIG. 8, wherein completed insertion of the adapter 20 within the battery mating system 93 is illustrated, in accordance with a preferred embodiment of the present invention.

FIG. 10 is an elevated perspective top view of the platform battery 90 shown in FIGS. 8 and 9.

FIG. 11 is an elevated perspective bottom view of the platform battery 90 shown in FIGS. 8 and 9.

The imaging system 100 comprises a stand 10 including a platform 11 and an upwardly extending threaded male fastener 12 provided at the platform 11. The imaging system 100 also comprises an adapter 20 comprising a main body 21, wherein the main body 21 comprises a main body bottom 21b and a main body top 21t, and wherein the main body bottom 21b includes a female threaded hole 22 that threadably mates with the male fastener 12 of the stand 10. The adapter 20 also comprises a flange 25 provided at the main body top 21t. The imaging system 100 further comprises an imaging device 80 comprising a housing 81 including a housing bottom 81b. The imaging device 80 also comprises a mating system 83 that removably secures the adapter 20. The imaging device 80 is removably secured to the stand 10 via the adapter 20.

The mating system 83 is provided at the housing bottom 81b. The housing bottom 81b and mating system 83 are free of female threaded holes that threadably mate with the male fastener 12 of the stand 10. The mating system 83 includes a slot system 84 that removably secures the flange 25 of the adapter 20 while the adapter 20 is inserted within the mating system 83.

The mating system 83 includes an elastic tongue 87 that abuts the main body 21 of the adapter 20 while the adapter 20 is inserted within the mating system 83 and while the elastic tongue 87 is in an unstressed position. The mating system 83 includes an elastic tongue 87 that is in a stressed position during the insertion of the adapter 20 within the mating system 83 and during removal of the adapter 20 from the mating system 83. The elastic tongue 87 and slot system 84 combination thus enables a snap-fit securement.

The main body 21 may optionally be rotatable with respect to the flange 25 via a circular slidable interface 29. Interface 29 may be located within any axial distance from the female threaded hole 22 and may extend cylindrically from the main body top 21t to the main body bottom 21b. Interface 29 may comprise any low friction interface/material such as Teflon® or ball bearings. When the adapter is removably secured to the stand via the threaded arrangement (i.e. female threaded hole 22 and threaded male fastener 12), the female threaded hole 22 is stable while the interface 29 allows for the flange 25 to be rotatable with respect to the female threaded hole 22, thereby allowing the imaging device 80 to rotate on the stand while being secured to the stand via the adapter 20.

The imaging device 80 may further comprise a removable platform battery 90 having a battery top 90t a battery bottom 90b, and wherein the mating system is a battery mating system 93 which is provided at the battery bottom 90b.

Alternatively, the imaging device 80 may further comprise a removable platform battery 90 having a battery top 90t a battery bottom 90b, and wherein a battery mating system 93 that removably secures the adapter is provided at the battery bottom 90b. The battery top 90t preferably includes a recess 95, wherein the mating system 83 provided at the housing bottom 81b resides at least partly within the recess 95 when the battery 90 is connected to the housing bottom 81b.

The battery mating system 93 preferably comprises the same structure and preferably provides the same function as that of the mating system 83 at the housing bottom 81b. Either or both the battery mating system 93 (i.e. when employing a platform battery 90) or the mating system 83 at the housing bottom 81b may be employed.

The imaging device 80 may be a projector or a recording device such as a still camera or video camera/recorder.

The contemplated modifications and variations specifically mentioned above and below are considered to be within the spirit and scope of the present invention.

Those of ordinary skill in the art will recognize that various modifications and variations may be made to the embodiments described above without departing from the spirit and scope of the present invention. For example, although the threaded arrangement is described above as comprising a female threaded hole 22 and threaded male fastener 12 provided within the adapter 20 and at the platform 11 of the stand 10, respectively, the female threaded hole 22 and threaded male fastener 12 arrangement may be reversed. In other words, the female threaded hole 22 may be provided at the platform 11 of the stand 10, while the threaded male fastener 12 may be provided on the adapter. It is therefore to be understood that the present invention is not limited to the particular embodiments disclosed above, but it is intended to cover such modifications and variations as defined by the following claims.

What is claimed is:

1. An imaging system comprising:
a stand including a platform and an upwardly extending threaded male fastener provided at the platform;
an adapter comprising:
a main body, wherein the main body comprises a main body bottom and a main body top, and wherein the main body bottom includes a female threaded hole that threadably mates with the male fastener of the stand; and
a flange provided at the main body top;
an imaging device comprising:
a housing including a housing bottom; and
a mating system that removably secures the adapter;
wherein the imaging device is removably secured to the stand via the adapter.

2. The system of claim 1, wherein the mating system is provided at the housing bottom.

3. The system of claim 2, wherein the housing bottom and mating system are free of female threaded holes that threadably mate with the male fastener of the stand.

4. The system of claim 1, wherein the mating system includes a slot system that removably secures the flange of the adapter while the adapter is inserted within the mating system.

5. The system of claim 4, wherein the mating system includes an elastic tongue that abuts the main body of the adapter while the adapter is inserted within the mating system and while the elastic tongue is in an unstressed position.

6. The system of claim 1, wherein the mating system includes an elastic tongue that is in a stressed position during the insertion of the adapter within the mating system and during removal of the adapter from the mating system.

7. The system of claim 1, wherein the flange is rotatable with respect to the female threaded hole via a circular slidable interface, while the adapter is removably secured to the stand.

8. The system of claim 1, wherein the imaging device further comprises a removable platform battery having a battery top a battery bottom, and wherein the mating system is a battery mating system which is provided at the battery bottom.

9. The system of claim 2, wherein the imaging device further comprises a removable platform battery having a battery top a battery bottom, and wherein a battery mating system that removably secures the adapter is provided at the battery bottom.

10. The system of claim 9, wherein the battery top includes a recess, wherein the mating system provided at the housing bottom resides at least partly within the recess when the battery is connected to the housing bottom.

11. The system of claim 1, wherein the imaging device is a projector.

12. The system of claim 1, wherein the imaging device is a recording device.
